(19) United States
(12) Patent Application Publication
(10) Pub. No.: US 2025/0232404 A1
(43) Pub. Date: Jul. 17, 2025

(54) Super Resolution with Reduced Input Data Volume

(71) Applicant: Siemens Healthineers AG, Forchheim (DE)

(72) Inventor: Mario Zeller, Erlangen (DE)

(73) Assignee: Siemens Healthineers AG, Forchheim (DE)

(21) Appl. No.: 19/026,750

(22) Filed: Jan. 17, 2025

(30) Foreign Application Priority Data
Jan. 17, 2024 (DE) 10 2024 200 383.2

(51) Int. Cl. G06T 3/4053; G06T 5/80; G06T 11/00

(52) U.S. Cl. CPC G06T 3/4053; G06T 5/80; G06T 11/005; G06T 2207/10088

(57) ABSTRACT

A method for generating magnetic resonance image data of an object under examination with increased resolution is described. In the method, oversampled k-space data is received from a region of interest of the object under examination, wherein the oversampled k-space data is obtained by oversampling in the phase-encoding direction with a predetermined oversampling factor greater than 1. Magnetic resonance image data is reconstructed based on the sampled k-space data, with an image region that is enlarged by the oversampling factor relative to the region of interest. In addition, reduced magnetic resonance image data is generated by reducing the size of the enlarged image region in the phase-encoding direction. Finally, image data with increased resolution is generated by applying a super-resolution method to the reduced magnetic resonance image data. An image data generating device is also described. In addition, a magnetic resonance imaging system is described.

### TECHNICAL FIELD

The disclosure relates to a method for generating magnetic resonance image data of an object under examination with increased resolution. The disclosure also relates to an image data generating device. The disclosure further relates to a magnetic resonance imaging system.

### BACKGROUND

Imaging systems based on a magnetic resonance measurement method, particularly of nuclear spins, so-called MRI scanners, have become successfully established and proven in a wide range of applications. In this form of image acquisition, a static main magnetic field Bo used for initial alignment and homogenization of the magnetic dipoles to be examined is typically superimposed with a rapidly switched magnetic field, the so-called gradient field, for spatial resolution of the imaging signal. To determine material properties of an object under examination, the dephasing or relaxation time after displacement of the magnetization from the initial alignment is determined so that different material-typical relaxation mechanisms or relaxation times can be identified. The displacement is usually produced by a number of radiofrequency (RF) pulses, also referred to as excitation pulses, and the spatial resolution is based on a time-defined manipulation of the displaced magnetization using the gradient field in a so-called measurement sequence or excitation sequence that defines an exact time sequence of RF pulses, the change in the gradient field (by the transmission of a switching sequence of gradient pulses) and the acquisition of measured values.

Typically, a correlation between measured magnetization—from which the material properties referred to can be derived—and a spatial coordinate of the measured magnetization in the spatial domain in which the object under examination is located, is achieved via an intermediate step. In this intermediate step, acquired raw magnetic resonance data, also referred to as k-space data, is disposed at readout points in so-called “k-space”, wherein the k-space coordinates are encoded as a function of the gradient field. The magnitude of the magnetization (in particular, the transverse magnetization in a plane perpendicular to the above-described main magnetic field) at a specific location in the object under examination can be determined from the readout-point data using a Fourier transform which calculates the spatial-domain signal strength from a signal strength (magnitude of the magnetization) associated with a specific frequency (the spatial frequency) or phase.

However, k-space is often only partially sampled to save time, and this reduced sampling of the k-space results in a reduction in the image information reconstructed on the basis of the sampled k-space data, particularly in a reduction in the image resolution. To compensate for this loss of information, various methods have been developed to address undersampling. These methods can involve both augmenting k-space data and also directly increasing resolution in the image data domain.

Super resolution is a means of enhancing the image quality of magnetic resonance imaging in terms of improving image resolution in the image data domain. Super resolution can be achieved by machine-learning-based algorithms which aim to increase the resolution of an image, often by a factor of four or more. A special type of machine learning, known as “deep learning”, uses an artificial neural network with numerous intermediate layers between the input layer and the output layer.

Deep Resolve Sharp (DRS) is a method for interpolating MR images using a neural super-resolution network based on deep learning. Such a method is described in Yulun Zhang et al. “Residual Dense Network for Image Super-Resolution.” Proceedings of the IEEE conference on computer vision and pattern recognition 2018.

Compared to conventional interpolation methods, such as bicubic interpolation or k-space-based zero filling, images interpolated using DRS generally have a higher image sharpness, as the artificial neural network used for the interpolation process has been trained on a large number of edge types.

A disadvantage of DRS is that the algorithm implemented by the artificial neural network is time-consuming to run. It is also used on so-called “low-cost” free-platform scanners, which often lack a graphics processor (GPU) and only have a weak CPU. Accordingly, it can take several seconds to interpolate a single slice.

A large number of MR datasets are acquired using a process known as phase oversampling. In this process, the acquired field of view, i.e., the image acquisition area that should encompass the region of interest, is selected a factor f larger than the FoV actually of interest in the phase-encoding direction. On the one hand, this increases the signal-to-noise ratio (SNR), which is proportional to the square root of the number of k-space lines acquired. On the other hand, unwanted aliasing artifacts are shifted into the oversampling region and are, therefore, not visible in the final image.

In MR imaging, tailoring of the oversampled FoV typically occurs only at the end of the processing chain. This is partly due to the fact that, in a high proportion of cases, the number of pixels in the frequency-encoding direction is not equal to the number of pixels in the phase-encoding direction. This disparity is compensated for in a final step, irrespective of the interpolation method used, by means of zero filling, wherein unsampled areas of the FoV are assigned the value “0”. If the FOV were to be cropped in advance, this would have a negative effect on image quality.

Consequently, DRS is also usually performed on the entire oversampled FoV. With a maximum possible phase oversampling of 200%, this results in a tripling of the reconstruction time.

A conventional reconstruction method with super resolution is shown in FIG. 1. The method illustrated in FIG. 1 involves interpolation in the readout direction and in the phase-encoding direction. This is followed by an inverse Fourier transform into the k-space. In the k-space, the distorted aspect ratio (caused by differing phase resolution) of the k-space region occupied by raw magnetic resonance data is adjusted. Subsequently, an inverse transformation of the adjusted k-space data into the image data domain takes place. Finally, unnecessary border regions in the phase-encoding direction are cropped to obtain the final image with the desired target FoV.

With phase oversampling of 200%, as in the case shown in FIG. 1, 200% of the field of view is interpolated “unnecessarily” by a super-resolution network, since this region will be cropped in the final step of the conventional method and thus discarded. Because the interpolation requires computing time, the interpolation process is significantly prolonged.

### SUMMARY

Thus, an object of the disclosure in the context of magnetic resonance imaging is to reduce the processing time compared to conventional methods while achieving increased resolution of magnetic resonance image data through super resolution, particularly using DRS, while maintaining at least the same image quality.

This object is achieved by a method for generating magnetic resonance image data of an object under examination at an increased resolution, by an image data generating device, and by a magnetic resonance imaging system.

In the method according to the disclosure for generating magnetic resonance image data of an object under examination with increased resolution, oversampled k-space data is received from a region of interest of the object under examination. The oversampled k-space data is obtained by oversampling in the phase-encoding direction using a predetermined oversampling factor greater than 1. The term k-space refers to the respective space in which the measured raw data is sampled or measured. A value of 2 is preferably used for the oversampling factor.

Based on the sampled k-space data, magnetic resonance image data is reconstructed with an image region enlarged by the oversampling factor relative to the region of interest.

Reduced magnetic resonance image data is generated by reducing the size of the enlarged image region in the phase-encoding direction. This “reduced” magnetic resonance image data forms the starting point for generating image data with increased resolution (i.e., with higher resolution than the magnetic resonance image data that has not yet been processed by the inventive method) using a super-resolution algorithm, preferably based on the DRS principle already explained. Since the time required by this algorithm depends on the amount of input data, reducing the image region accelerates the super-resolution process.

Finally, image data with increased resolution is generated by applying a super-resolution method to the reduced magnetic resonance image data. The effects of the reductions in the amount of data on any subsequent correction steps are preferably compensated by a subsequent format adjustment in the image data domain, as will be explained in detail below. Any initial unequal sampling of the region of interest in the phase-encoding and readout directions is balanced out by a format adjustment in the k-space domain. Details regarding this will be provided in connection with advantageous variants of the inventive method.

The reduction in the volume of input data advantageously means that an existing standard algorithm based on the super-resolution principle for increasing image resolution, in particular the DRS algorithm, which is particularly time-consuming, can be used in a particularly time-saving manner but without loss of image quality, as compensatory formatting adjustments are performed as required, after the application of the super resolution algorithm, in the image data and k-space domains to compensate for interpolation-related artifacts. In particular, the reconstruction time can be made independent of the degree of oversampling, since the image data to be interpolated can be limited to a predetermined format by the described reduction step, irrespective of the oversampling factor.

The image data generating device, according to the disclosure, has an input interface for receiving k-space data from a region of interest of the object under examination. Oversampling takes place in the phase-encoding direction with a predetermined oversampling factor greater than 1.

The image data generating device, according to the disclosure, comprises a reconstruction unit for reconstructing magnetic resonance image data based on the sampled k-space data, with an image region enlarged by the oversampling factor relative to the region of interest.

In order to reduce the input data for a super-resolution algorithm, the inventive image data generating device also has a reduction unit for generating reduced magnetic resonance image data by reducing the enlarged image region in the phase-encoding direction.

To generate image data with increased resolution by applying a super-resolution method to the reduced magnetic resonance image data, the image data generating device according to the disclosure has a super-resolution unit. The inventive image data generating device shares the advantages of the inventive method for generating magnetic resonance image data of an object under examination with increased resolution.

The magnetic resonance imaging system, according to the disclosure, has the inventive image data generating device. The magnetic resonance imaging system, according to the disclosure, shares the advantages of the inventive method for generating magnetic resonance image data of an object under examination with increased resolution.

A majority of the aforementioned components of the image data generating device, according to the disclosure, can be wholly or partly implemented in the form of software modules in a processor of a corresponding computing system, e.g., by a control device of a magnetic resonance imaging system or a computer used to control such a system. The advantage of a largely software-based implementation is that even previously used computing systems can be easily upgraded with a software update to operate in an inventive manner. In this respect, the object is also achieved by a corresponding computer program product comprising a computer program that can be loaded directly into a computing system, having program sections for carrying out the steps of the inventive method for generating magnetic resonance image data of an object under examination with increased resolution when the program is executed in the computing system. In addition to the computer program, such a computer program product may also include additional elements, such as documentation and/or additional components, including hardware components such as hardware keys (dongles, etc.) for using the software.

A computer-readable medium, e.g. a memory stick, a hard disk, or other portable or fixed data carrier, on which are stored the program sections of the computer program that can be read and executed by a computing system, can be used for transferring to the computing system or to the control device and/or for storage on or in the computing system or the control device. The computing system may include one or more cooperating microprocessors or similar components for this purpose.

The dependent claims and the following description each contain particularly advantageous aspects and further developments of the disclosure. In particular, the claims of one category of claims may also be further developed analogously to the dependent claims of another category. In addition, within the scope of the disclosure, the various features of different exemplary aspects and claims can also be combined to form new exemplary aspects.

In a variant of the inventive method for generating magnetic resonance image data of an object under examination with increased resolution, if the number of pixels of the reconstructed magnetic resonance image data in the phase-coding direction and readout directions is identical, the generation of image data with increased resolution involves generating high-resolution image data by applying a super-resolution method to the reduced magnetic resonance image data. If the number of pixels of the image data in the frequency-encoding direction and phase-encoding direction is identical, the aforementioned format adjustment steps can be omitted after the resolution has been increased by means of super resolution.

In the event that the number of pixels of the reconstructed magnetic resonance image data in the phase-encoding direction and readout direction is not identical, the step of generating image data with increased resolution by applying a super-resolution method to the reduced magnetic resonance image data comprises the following sub-steps:
generating image data with increased resolution by applying a super-resolution method to the reduced magnetic resonance image data,
correcting image distortions resulting from the inequality in the number of pixels of the reconstructed magnetic resonance image data in the phase-encoding direction and readout directions, wherein formatted undistorted image data with increased resolution is generated.

In this particularly advantageous variant, it is advantageous to perform format adjustment after the generation of image data with increased resolution, whereby artifacts caused by interpolation are compensated for while reducing reconstruction time.

In most cases, the reconstructed magnetic resonance image data has a lower resolution in the phase-encoding direction than in the readout direction. For example, the reconstructed magnetic resonance image data has 80% of the resolution in the readout direction. This inequality is compensated for in the correction step to balance out the aspect ratio distorted by the differing phase resolution.

The correction step preferably comprises the following sub-steps:
creating inserted image data by inserting the image data with increased resolution into a target matrix whose format corresponds to the format of image data with increased resolution that would have been achieved using the super-resolution method if the enlarged image region had not been reduced in the phase-encoding direction,
transforming the inserted image data into k-space, wherein augmented k-space data is generated,
generating inserted k-space data by inserting the augmented k-space data into a target matrix, the format of which corresponds to equal sampling in the phase-encoding direction and readout direction,
transforming the inserted k-space data into the image data domain, wherein undistorted high-resolution image data with border regions containing no image information in the phase-encoding direction is generated,
generating the formatted undistorted high-resolution image data by cropping the border regions.

Generating the inserted image data is advantageous for compensating for the differences in interpolation and deviations in pixel dimensions caused by reducing the format of the super-resolution input data, which differences and deviations would occur if so-called “zero filling” in k-space, i.e. generating the inserted k-space data, were to be carried out directly based on the super-resolution output data.

Particularly preferred is the use of an empty matrix as the target matrix for the step of generating the inserted image data. Since the target matrix is only required for format adjustment, it can advantageously be empty, containing no data that would impose computational overhead during transformation into k-space.

In an alternative aspect of the inventive method for generating magnetic resonance image data of an object under examination with increased resolution, generating image data with increased resolution involves, in addition to applying the super-resolution method to the reduced magnetic resonance image data, also applying the super-resolution method to the magnetic resonance image data with an enlarged image region. In this process, the conventional image data generated with increased resolution when the super-resolution method is applied to the magnetic resonance image data with an enlarged image region is used as the target matrix in the step of generating inserted image data with increased resolution.

Thus, in this variant, in parallel with the interpolation of the reduced magnetic resonance image data generated by the inventive image reduction step using a super-resolution network, conventional interpolation of the reconstructed image data—available with an enlarged image region due to oversampling—also takes place, wherein conventional high-resolution image data is obtained. Conventional interpolation of this kind is preferably realized by bicubic interpolation or k-space-based zero-filling. This conventional high-resolution image data already has the format of the inserted high-resolution image data obtained in the inventive method by insertion into a target matrix, in particular, an empty matrix. Instead of being inserted into an empty matrix, the image data based on the reduced magnetic resonance image data and generated by super-resolution is inserted into the conventional high-resolution image data, covering the center region thereof.

This “hybrid” approach can be advantageous when access to the entire FoV, i.e. the enlarged image region, is still required after applying the inventive method. For example, the enlarged image region can be used for automated determination of image statistics, such as determining a median value, determining a maximum intensity value, or searching for landmarks, the user only being interested in viewing the smaller-format, formatted high-resolution image data. Since conventional interpolation is significantly faster than super-resolution-based interpolation, a time saving is achieved overall despite the enlarged image region being inputted into the conventional interpolation algorithm.

For reducing the format of the image data used as input data for the super-resolution algorithm, a variant involves selecting the format of the reduced magnetic resonance image data such that it has the same dimensions as the region of interest. In this variant, the volume of input data for the super-resolution algorithm is minimal, which is advantageous in terms of reconstruction time.

However, practical experience has shown that a slightly larger image data format for the input data is more favorable for minimizing differences in interpolation in the border region, compared to the output data generated by the super-resolution algorithm based on conventional input data. These effects are likely caused by the size of the filter kernels in the network architecture of the super-resolution network, wherein artifacts can occur due to cyclic permutation in the border region, as well as so-called ringing artifacts associated with zero filling. To avoid these artifacts, the format of the reduced magnetic resonance image data is preferably selected such that it is greater than the dimensions of the region of interest by a predetermined value in the phase-encoding direction. This value can be determined experimentally, the requirement being a minimum quality of the image data in the border region.

The predetermined value is preferably set as a fixed number of pixels, such as 10 pixels. In this variant, the “safety margin areas” are always the same size, regardless of the number of pixels in the FoV. One advantage of this variant is that, for data with few pixels, a sufficient safety margin is still retained, while for data with a large number of pixels, the computational overhead is reduced because the increase is limited to a maximum of 10 pixels.

With particular preference, the predetermined value comprises a proportional value of pixels that result from the oversampling factor. It has proven especially effective if the proportional number of pixels corresponds to a safety margin that constitutes 10% of the additional image region generated by oversampling in the phase-encoding direction. This advantageously avoids the edge artifacts mentioned above, while the time loss due to the minimally increased image data volume is negligible.

If the resolution of the reconstructed magnetic resonance image data at an oversampling factor of 1 is 320 pixels in the frequency-encoding direction, i.e. the readout direction, the resolution in the phase-encoding direction at 80% phase resolution is 256 lines. For 256 phase-encoding lines with 200% oversampling, the FoV extent in the phase-encoding direction is thus 768 pixels. Assuming a safety margin of 10%, the reduced area to be interpolated for dimensioning the reduced magnetic resonance image data is then 768/(1+2.0−0.1)=264 pixels. A reverse rule-of-three calculation to a hypothetical phase oversampling of 10%, i.e., 256 pixels*(100%+200%)/(100%+200%−10%), is thus performed.

In the super-resolution network, the selected section is then interpolated to double its size, i.e. to 640*528 pixels in the example given, generating high-resolution image data.

In the subsequent step, which is also innovative, the high-resolution image data HBD is inserted into an empty target matrix whose dimensions correspond to the size that would have been achieved if the image regions resulting from oversampling had not been removed before applying super resolution. In the example provided, this corresponds to a target matrix with dimensions of 640*1536 pixels. This step aims to ensure that, in a later step for compensating the unequal resolution ratios between the phase-encoding direction and the readout direction, a consistent interpolation result is obtained.

### DESCRIPTION OF THE DRAWINGS

The disclosure will now be explained again in more detail with reference to the accompanying drawings based on exemplary aspects, wherein:

FIG. 1 shows a schematic diagram illustrating a conventional method for generating magnetic resonance image data of an object under examination with increased resolution,

FIG. 2 shows a schematic diagram illustrating a method for generating magnetic resonance image data of an object under examination with increased resolution according to an exemplary aspect of the disclosure,

FIG. 3 shows a flowchart illustrating a method, as exemplified in FIG. 2, for generating magnetic resonance image data of an object under examination with increased resolution according to an exemplary aspect of the disclosure,

FIG. 4 shows a flowchart illustrating a method for generating magnetic resonance image data of an object under examination with increased resolution according to an alternative exemplary aspect of the disclosure,

FIG. 5 schematically illustrates an image data generating device according to an exemplary aspect of the disclosure, and

FIG. 6 shows a magnetic resonance imaging system according to an exemplary aspect of the disclosure.

### DETAILED DESCRIPTION

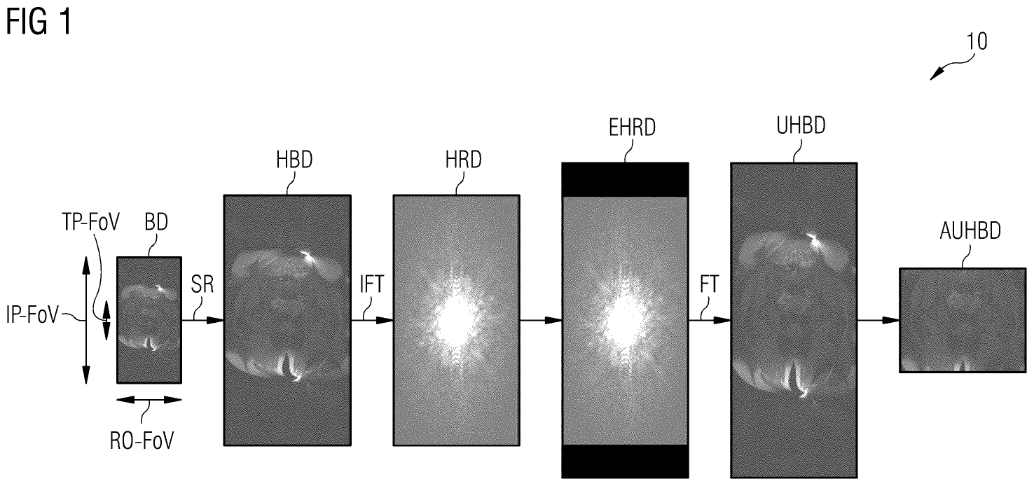

FIG. 1 shows a schematic diagram 10 illustrating a conventional method for generating magnetic resonance image data of an object under examination with increased resolution.

The conventional method is initially based on image data BD that has been generated by oversampling and thus by enlarging the dimensions TP-FOV of the field of view in the phase-encoding direction. That is to say, the dimensions of the field of view IP-FOV in the vertical direction have been tripled, corresponding to a phase oversampling of 200%. The dimensions RO-FoV of the field of view in the readout direction remain unchanged. The oversampled field of view is then interpolated by a super-resolution network to twice its dimensions or four times its area, thereby generating high-resolution image data HBD. An inverse Fourier transform IFT is then applied to the high-resolution image data HBD, transforming it back into k-space and generating high-resolution k-space data HRD. The k-space is then inserted into a target k-space enlarged from 80% to 100% in the phase-encoding direction. The resulting inserted high-resolution k-space data EHRD is then transformed back into the image data domain by Fourier transformation FT to compensate for the image data's distorted aspect ratio caused by the differing phase resolutions. The Fourier transform FT thus generates undistorted high-resolution image data UHBD. As a final step, the target field of view is cropped in the phase-encoding direction, generating cropped undistorted high-resolution image data AUHBD. As explained above, while this approach yields high-resolution, undistorted image data, the time required for applying super resolution is considerable, since this process is applied to the field of view with enlarged dimensions TP-FoV, even though large portions of this field of view do not contain any image data of interest.

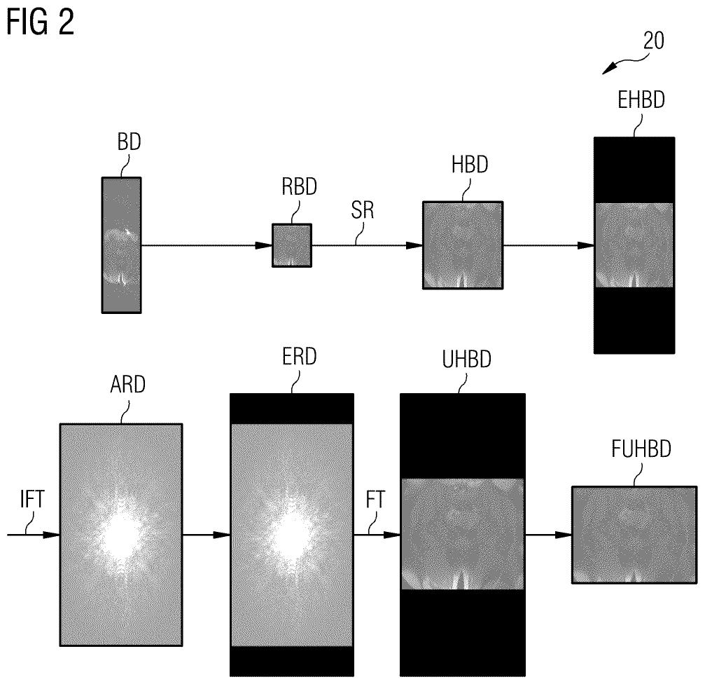

FIG. 2 shows a schematic diagram 20 illustrating a method for generating magnetic resonance image data of an object under examination with increased resolution according to an exemplary aspect of the disclosure.

The initial step of the method shown in FIG. 2 corresponds to the conventional procedure illustrated in FIG. 1, wherein the inventive method is initially based on image data BD that has been generated by oversampling and thus by enlarging the field of view FoV in the phase-encoding direction. That is to say, the dimensions IP-FOV of the field of view FoV in the vertical or phase-encoding direction have been tripled, corresponding to 200% oversampling in the phase direction. The dimensions RO-FOV of the field of view in the readout direction remain unchanged.

Next, in an innovative step, a large portion of the image area generated by oversampling in the phase-encoding direction, and containing no relevant image information anyway, is removed so that the reduced image data RBD produced as a result exhibits smaller or reduced dimensions in the phase-encoding direction.

This reduced image data RBD is then used as input data for a super-resolution network. In principle, the area of this reduced image data RBD can correspond exactly to the target field of view or, rather, its dimensions TP-FoV. However, it is advantageous to select the format of the reduced image data RBD slightly larger than the dimensions TP-FOV of the target field of view in order to minimize differences in interpolation in the boundary region of the target field of view compared to the conventional method. These differences may be related to the size of the filter kernels of the network architecture and potential effects of cyclic permutation at the boundary, as well as ringing effects. For this reason, a “safety margin” of 10% of the oversampling is used. Alternatively, a safety margin with a fixed number of pixels can also be applied.

The super-resolution network then performs interpolation on the selected section to double its size, i.e. double its length and width, thereby generating high-resolution image data HBD.

In the following step, which is also innovative, the high-resolution image data HBD is inserted into an empty target matrix whose dimensions correspond to those that would have been obtained if the image regions generated by oversampling had not been removed prior to applying super resolution. In this process, inserted high-resolution image data EHBD is generated with empty border regions (black areas in FIG. 2). The purpose of this step is to ensure that a usual interpolation result is obtained in a subsequent step to equalize the unequal resolution ratio between the phase-encoding direction and the readout direction.

This is followed by inverse Fourier transformation IFT of the high-resolution image data HBD into k-space, generating augmented k-space data ARD.

Subsequently, a step known as “zero filling” is carried out to align the formatting of the augmented k-space data ARD in the phase-encoding direction with the dimensioning in the readout direction, wherein the augmented k-space data ARD is inserted into an enlarged target matrix, so that inserted k-space data ERD with “empty” border regions (black areas in FIG. 2) is obtained.

The inserted k-space data ERD is then transformed into the image data domain by Fourier transformation, wherein undistorted high-resolution image data UHBD with empty border regions (black areas in FIG. 2) containing no image information is generated in the phase-encoding direction. These border regions without image information are removed in a final step, wherein the undistorted high-resolution image data UHBD is tailored to the final aspect ratio, thereby producing formatted undistorted high-resolution image data FUHBD by cropping the border regions. Unlike the final step in the conventional approach, most of the image area associated with oversampling in the undistorted high-resolution image data UHBD contains no data. However, since these regions are removed by cropping, this does not present any issues.

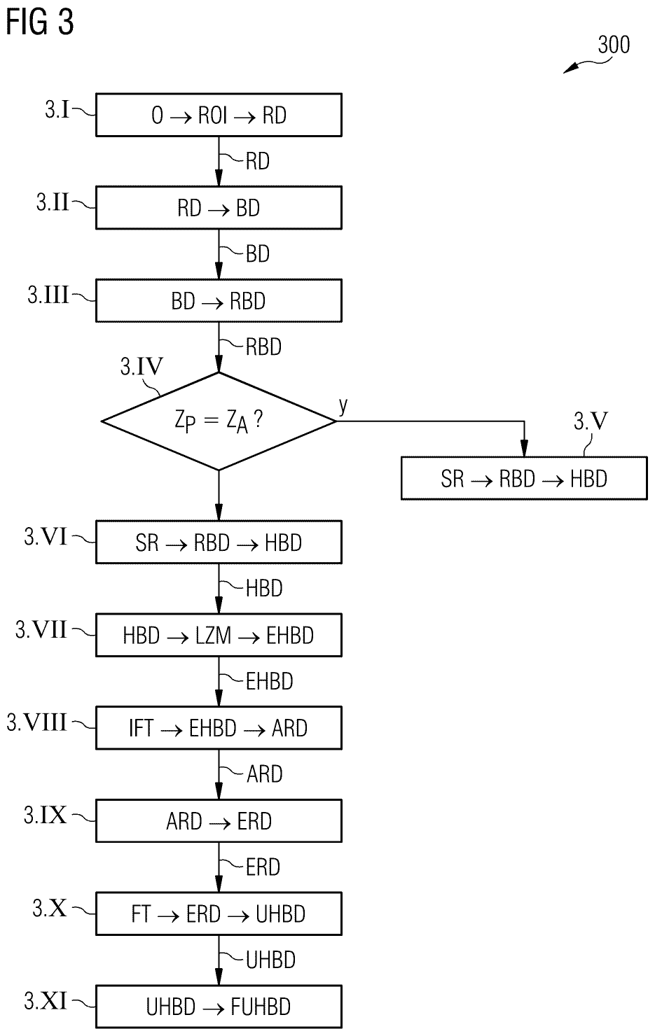

FIG. 3 shows a flowchart 300 illustrating the method, exemplified in FIG. 2, for generating magnetic resonance image data of an object under examination with increased resolution according to an exemplary aspect of the disclosure.

In step 3.I, oversampled k-space data RD is first received from a region of interest ROI of an object under examination O. The oversampled k-space data RD has been obtained by oversampling in the phase-encoding direction with a predetermined oversampling factor greater than 1.

In step 3.II, magnetic resonance image data BD is reconstructed based on the oversampled k-space data RD with an image region enlarged relative to the region of interest ROI by the oversampling factor.

In step 3.III, reduced magnetic resonance image data RBD is generated by reducing the enlarged image region in the phase-encoding direction.

In step 3.IV, it is determined whether the number Z_{P}, Z_{A} of pixels in the reconstructed magnetic resonance image data BD is identical in the phase-encoding and readout directions. If the number of pixels Z_{P}, Z_{A} in the reconstructed magnetic resonance image data BD is identical in the phase-encoding and readout directions, as indicated by “y” in FIG. 3, the process advances to step 3.V. In step 3.V, high-resolution image data HBD is directly generated by applying a super-resolution method to the reduced magnetic resonance image data RBD. However, if it was determined in step 3.IV that the number of pixels Z_{P}, Z_{A} in the reconstructed magnetic resonance image data BD in the phase-encoding and readout direction is not identical, as indicated by “n” in FIG. 3, the process advances to step 3.VI.

In step 3.VI, high-resolution image data HBD is obtained by applying a super-resolution method to the reduced magnetic resonance image data RBD. In this case, however, there is still an asymmetry in the resolution of the high-resolution image data HBD between the phase-encoding and readout directions. If so-called zero filling were now applied directly to the high-resolution image data HBD to compensate for said asymmetry, this would cause the results of the interpolation to deviate from those of the conventional procedure, and changes in the pixel dimensions would also occur.

In order to avoid these deviations, the high-resolution image data EHBD that was inserted in step 3.VII is generated by inserting the image data HBD with increased resolution into an empty target matrix LZM whose format corresponds to the format of image data with increased resolution that would have been obtained by applying the super-resolution method if the enlarged image region in the phase-encoding direction had not been reduced.

The inserted high-resolution image data EHBD is then used as the basis for the “zero filling” that is also conventionally employed. For this purpose, the inserted high-resolution image data EHBD is transformed into k-space in step 3.VIII by means of an inverse Fourier transform IFT, generating augmented k-space data ARD.

In step 3.IX, the inserted k-space data ERD is generated by inserting the augmented k-space data ARD into a target matrix formatted for equal sampling in the phase-encoding and readout directions.

In step 3.X, the inserted k-space data ERD is transformed into the image data domain, wherein undistorted high-resolution image data UHBD with border regions containing no image information in the phase-encoding direction is generated.

In step 3.XI, the formatted undistorted high-resolution image data FUHBD is generated by cropping the border regions.

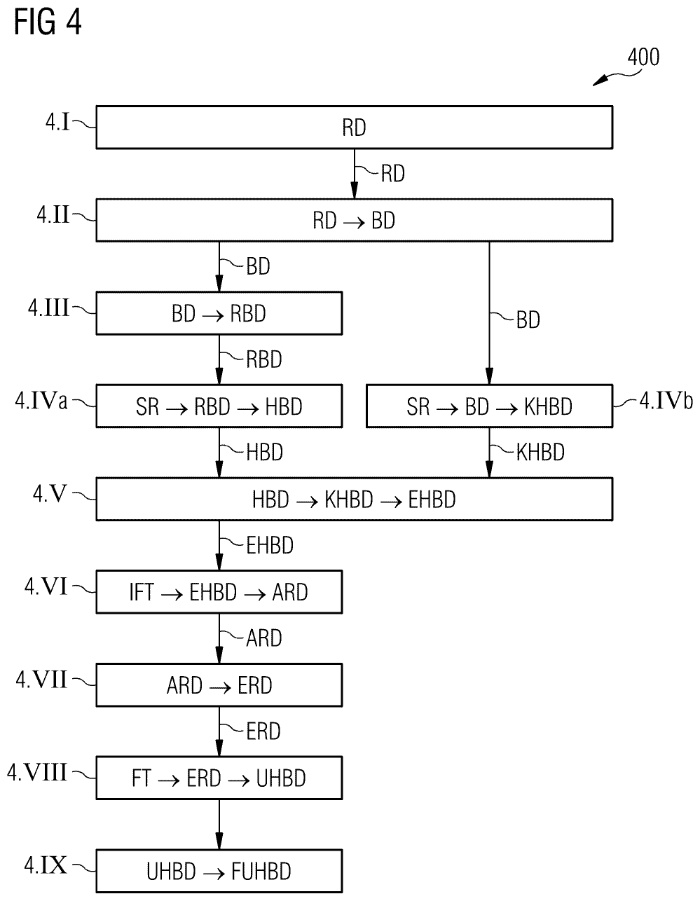

FIG. 4 shows a flowchart 400 illustrating a method for generating magnetic resonance image data of an object under examination with increased resolution according to an alternative exemplary aspect of the disclosure. For the sake of simplicity, it is assumed in the exemplary aspect shown in FIG. 4 that the number of pixels Z_{P}, Z_{A} in the reconstructed magnetic resonance image data BD in the phase-encoding and readout direction is not identical and that adjustment of the format of the high-resolution image data HBD is therefore necessary prior to zero filling.

Steps 4.I to 4.IVa correspond to the steps 3.I to 3.III and 3.VI. In particular, in step 4.I, oversampled k-space data RD is first received from a region of interest ROI of the object under examination O. The oversampled k-space data RD was obtained by oversampling in the phase-encoding direction with a predetermined oversampling factor greater than 1.

In step 4.II, magnetic resonance image data BD is reconstructed based on the sampled k-space data RD with an image region enlarged relative to the region of interest ROI by the oversampling factor.

In step 4.III, reduced magnetic resonance image data RBD is generated by reducing the enlarged image region in the phase-encoding direction. The boundary regions away from the central region of the image data BD are cropped.

In step 4.IVa, image data HBD with increased resolution is obtained by applying a super-resolution method to the reduced magnetic resonance image data RBD. In this case, however, there is still an asymmetry in the resolution of the image data HBD between the phase-encoding and readout directions. If so-called “zero filling” were now applied directly to the high-resolution image data HBD to compensate for said asymmetry, this procedure would cause the results of the interpolation to deviate from those of the conventional procedure, and changes in the pixel dimensions would also occur.

In step 4.IVb, unlike the exemplary aspect illustrated in FIG. 3, conventional interpolation of the entire image data BD is now carried out in parallel with step 4.IVa, resulting in conventional high-resolution image data KHBD. This conventional high-resolution image data KHBD already has the format of the high-resolution image data EHBD obtained in step 3.VII, as shown in FIG. 3. Unlike the variant illustrated in FIG. 3, in step 4.V the high-resolution image data HBD obtained in step 4.IVa is inserted, not into a zero or empty matrix, but into the conventionally generated high-resolution image data KHBD to produce inserted high-resolution image data EHBD.

Steps 4.VI to 4.IX then correspond to steps 3.VIII to 3.XI.

In particular, in step 4. VI, the inserted high-resolution image data EHBD is used as the basis for the conventionally applied “zero filling”. For this purpose, the inserted high-resolution image data EHBD is transformed into the k-space in step 4. VI, thereby generating augmented k-space data ARD.

In step 4.VII, the inserted k-space data ERD is generated by inserting the augmented k-space data ARD into a target matrix whose format corresponds to identical sampling in the phase-encoding and readout directions.

In step 4. VIII, the inserted k-space data ERD is transformed into the image data domain, generating undistorted high-resolution image data UHBD, which, however, has border regions in the phase-encoding direction that contain image information.

In step 4.IX, the formatted undistorted high-resolution image data FUHBD is generated by cropping the border regions.

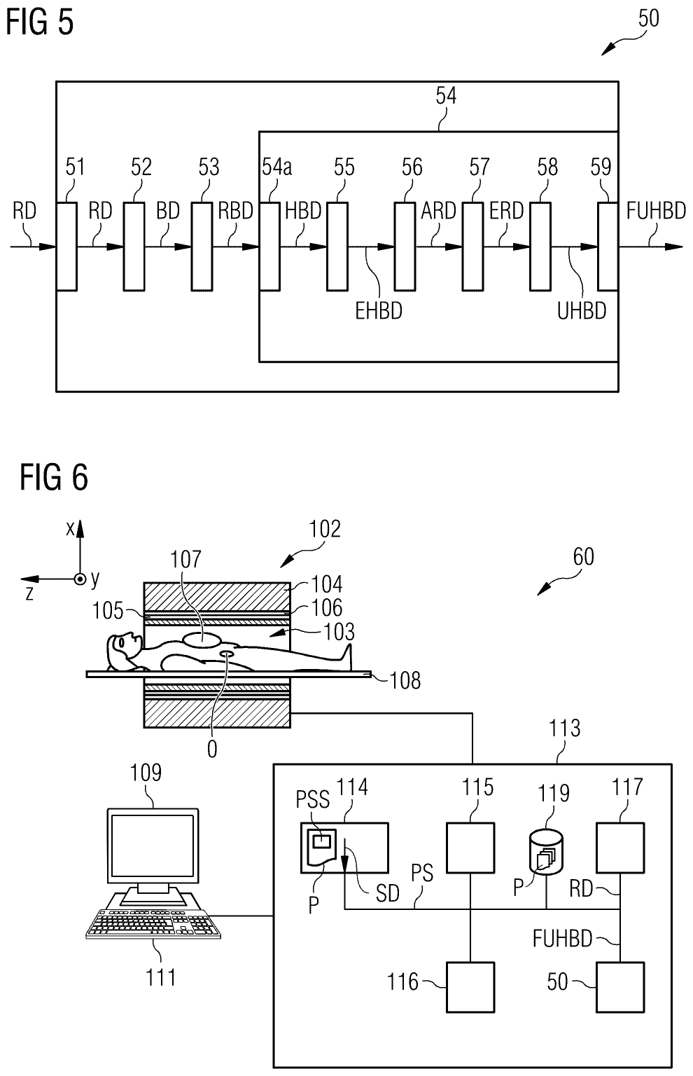

FIG. 5 schematically illustrates an image data generating device 50 according to an exemplary aspect of the disclosure.

The image data generating device 50 comprises an input interface 51 for receiving k-space data RD from a region of interest ROI of an object under examination O, wherein oversampling in the phase-encoding direction is performed with a predetermined oversampling factor greater than 1.

The image data generating device 50 also includes a reconstruction unit 52 for reconstructing magnetic resonance image data BD based on the oversampled k-space data RD, with an image region enlarged relative to the region of interest ROI by the oversampling factor.

The image data generating device 50 also comprises a reduction unit 53 for generating reduced magnetic resonance image data RBD by reducing the enlarged image region in the phase-encoding direction.

In addition, the image data generating device 50 comprises a super-resolution unit 54 for generating formatted undistorted high-resolution image data FUHBD by applying a super-resolution method to the reduced magnetic resonance image data RBD.

For this purpose, the super-resolution unit 54 has an interpolation unit 54a for generating image data HBD with increased resolution by applying a super-resolution method to the reduced magnetic resonance image data RBD.

The super-resolution unit 54 further comprises a matrix unit 55 for generating inserted high-resolution image data EHBD by inserting the image data HBD with increased resolution into an empty target matrix whose format corresponds to the format that would have been achieved for high-resolution image data on applying the super-resolution method if the enlarged image area had not been reduced in the phase-encoding direction.

The super-resolution unit 54 also includes a transformation unit 56 for transforming the inserted high-resolution image data EHBD into the k-space, thereby generating augmented k-space data ARD.

The super-resolution unit 54 additionally comprises an augmentation unit 57 for generating inserted k-space data ERD by inserting the augmented k-space data ARD into a target matrix whose format corresponds to identical sampling in the phase-encoding and readout directions.

The inserted k-space data ERD is transmitted to a back-transformation unit 58, which is also part of the super-resolution unit 54. The back-transformation unit 58 is designed to transform the inserted k-space data ERD into the image data domain, generating undistorted high-resolution image data UHBD with border regions in the phase-encoding direction that contain no image information.

The super-resolution unit 54 also has a cropping unit 59 for generating formatted undistorted high-resolution image data FUHBD by cutting off the border regions.

FIG. 6 shows a rough schematic of a magnetic resonance system 60 (hereinafter referred to as an “MR system”) according to the disclosure. It includes, on the one hand, the actual magnetic resonance scanner 102 with an examination space 103 or patient tunnel into which an object under examination O, or in this case a patient or test subject, can be moved on a table 108, so that, for example, a particular organ in the body can be imaged.

The magnetic resonance scanner 102 is equipped in the usual manner with a main field magnet system 104, a gradient system 106, an RF transmitting antenna system 105, and an RF receiving antenna system 107. In the exemplary aspect shown, the RF transmitting antenna system 105 is a whole-body coil permanently installed in the magnetic resonance scanner 102, while the RF receiving antenna system 107 consists of local coils to be placed on the patient or test subject (symbolized in FIG. 6 by a single local coil). In principle, however, the whole body coil 105 can also be used as an RF receiving antenna system and the local coils 107 as an RF transmitting antenna system, provided that these coils can each be switched to different operating modes.

The MR system 60 also has a central control device 113 that is used to control the MR system 60. This central control device 113 comprises a sequence control unit 114 for pulse sequence control. This is used to control the timing of radiofrequency (RF) pulses and gradient pulses in accordance with a selected imaging sequence PS as specified in a pulse sequence scheme PSS. Such an imaging sequence PS or rather the pulse sequence scheme PSS on which the imaging sequence PS is based can be predefined, for example, within a measurement or control protocol P. Usually, various control protocols P for different measurements are stored in a memory 119 and can be selected by an operator (and changed if necessary) and then used to perform the measurement.

To output the individual RF pulses, the central control device 113 has a radiofrequency transmitting device 115, which generates and amplifies the RF pulses and feeds them via a suitable interface (not shown in detail) into the RF transmitting antenna system 105. To control the gradient coils of the gradient system 106, the control device 113 has a gradient system interface 116. The sequence control unit 114 communicates in a suitable manner (e.g. by sending sequence control data SD) with the radio frequency transmitting device 115 and the gradient system interface 116 for outputting the pulse sequences PS. The control device 113 also comprises a radiofrequency receiving device 117 (also communicating in a suitable manner with the sequence control unit 114) for acquiring magnetic resonance signals received by the RF transmitting antenna system 107 in a coordinated manner. The central control device 113 also comprises an inventive image data generating unit 50 having the structure illustrated in detail in FIG. 5.

Also forming part of the image data generating device 50 is a reconstruction unit 52 (see FIG. 5) which takes over the acquired data, after demodulation and digitization, as raw data or k-space data RD and uses it to reconstruct magnetic resonance image data BD. This magnetic resonance image data BD is then optimized in terms of its resolution, and the formatted, undistorted, high-resolution magnetic resonance image data FUHBD generated in this way can then be stored, for example, in a memory 119.

The central control device 113 can be operated via a terminal having an input unit 111 and a display unit 109, allowing an operator to control the entire MR system 60. MR images can also be displayed on the display unit 109, and the input unit 111, possibly in combination with the display unit 109, can be used to plan and initiate measurements and, in particular, to select and possibly modify suitable control protocols with suitable measurement sequences as explained above.

The MR system 60, according to the disclosure and, in particular, the control device 113 may also have a variety of other components not shown in detail here but usually present in equipment of this kind, such as a network interface for connecting the entire system to a network and for exchanging raw data RD and/or image data BD or parameter maps, but also further data, such as patient-related data or control protocols.

How suitable raw data RD is acquired through the transmission of RF pulses and the generation of gradient fields, and how MR images BD are reconstructed from this, is generally known to persons skilled in the art and will not be explained in detail here.

The above description clearly shows that, in terms of the time required, the disclosure provides an effective means of improving a method for controlling a magnetic resonance imaging system for generating magnetic resonance image data.

It should be noted that the features of any exemplary aspect or further development disclosed in the figures can be used in any combination.

Finally, it should be noted that the detailed methods and structures described above are exemplary aspects and that the basic principle can also be varied in many ways by persons skilled in the art without departing from the scope of the disclosure as defined by the claims. For the sake of completeness, it should also be noted that the use of the indefinite articles “a” and “an” does not preclude the presence of a plurality of such features. Similarly, the term “unit” does not preclude it from consisting of a plurality of components that may also be spatially distributed. Independent of the grammatical term usage, individuals with male, female, or other gender identities are included within the term.

1. A method for generating magnetic resonance image data of an object under examination with increased resolution, comprising:
receiving oversampled k-space data of a region of interest of the object under examination, wherein the oversampled k-space data has been obtained by oversampling in a phase-encoding direction with a predetermined oversampling factor greater than 1;
reconstructing magnetic resonance image data based on the oversampled k-space data, with an image region enlarged by the oversampling factor relative to the region of interest;
generating reduced magnetic resonance image data by reducing the enlarged image region in the phase-encoding direction; and
generating image data with increased resolution by applying a super-resolution method to the reduced magnetic resonance image data.

2. The method as claimed in claim 1, wherein, in when a number of pixels in the reconstructed magnetic resonance image data is not identical in the phase-encoding direction and readout direction, the step of generating image data with increased resolution by applying a super-resolution method to the reduced magnetic resonance image data comprises the following sub-steps:
generating image data with increased resolution by applying a super-resolution method to the reduced magnetic resonance image data; and
correcting image distortions resulting from a disparity in the number of pixels in the reconstructed magnetic resonance image data in the phase-encoding direction and the readout direction, wherein formatted undistorted image data with increased resolution is generated.

3. The method as claimed in claim 2, wherein the correcting step comprises the following sub-steps:
generating inserted image data with increased resolution by inserting the image data with increased resolution into a target matrix whose format corresponds to the format of image data with increased resolution that would have been obtained on applying the super-resolution method if the enlarged image region had not been reduced in the phase-encoding direction;
transforming the inserted image data into the k-space, wherein augmented k-space data is generated;
generating inserted k-space data by inserting the augmented k-space data into a target matrix whose format corresponds to the format of the oversampled k-space data with equal sampling in the phase-encoding direction and the readout direction;
transforming the inserted k-space data into an image data domain, wherein undistorted high-resolution image data (UHBD) with border regions in the phase-encoding direction that contain no image information is generated; and
generating the formatted undistorted image data with increased resolution by cropping the border regions.

4. The method as claimed in claim 3, wherein the target matrix used in the step of generating inserted image data with increased resolution is an empty matrix.

5. The method as claimed in claim 3, wherein the generation of image data with increased resolution comprises applying the super-resolution method to the reduced magnetic resonance image data and also applying the super-resolution method to the magnetic resonance image data with enlarged image region, wherein conventional image data with increased resolution that is generated when the super-resolution method is applied to the magnetic resonance image data is used as a target matrix for the step of generating inserted image data with increased resolution.

6. The method as claimed in claim 1, wherein a format of the reduced magnetic resonance image data is selected such that it has dimensions of the region of interest.

7. The method as claimed in claim 1, wherein a format of the reduced magnetic resonance image data is selected larger than dimensions of the region of interest by a predetermined value in the phase-encoding direction.

8. The method as claimed in claim 7, wherein the predetermined value includes a proportional value of pixels resulting from the oversampling factor.

9. The method as claimed in claim 8, wherein the proportional value of pixels corresponds to a safety margin corresponding to 10% of the enlarged image region generated by the oversampling in the phase-encoding direction.

10. The method as claimed in claim 1, wherein dimensions of a field of view used for oversampling the k-space data in the phase-encoding direction are 80% of its dimensions in a readout direction.

11. An image data generating device, comprising:
an input interface configured to receive k-space data from a region of interest of an object under examination, wherein oversampling in a phase-encoding direction is performed with a predetermined oversampling factor greater than 1;
a reconstruction unit configured to reconstruct magnetic resonance image data based on sampled k-space data, with an image region enlarged by the oversampling factor relative to the region of interest;
a reduction unit configured to generate reduced magnetic resonance image data by reducing the enlarged image region in the phase-encoding direction; and
a super-resolution unit configured to generate image data with increased resolution by applying a super-resolution method to the reduced magnetic resonance image data.

12. The image data generating device as claimed in claim 11, wherein the super-resolution unit comprises the following sub-units which are used when the number of pixels in the reconstructed magnetic resonance image data is not identical in the phase-encoding direction and readout direction:
an interpolation unit configured to generate image data with increased resolution by applying a super-resolution method to the reduced magnetic resonance image data;
a matrix unit configured to generate inserted image data with increased resolution by inserting the image data with increased resolution into a target matrix whose format matches the format of image data with increased resolution that would have been obtained on applying the super-resolution method if the enlarged image region had not been reduced in the phase-encoding direction;
a transformation unit configured to transform the inserted image data with increased resolution into k-space, wherein augmented k-space data is generated;
an augmentation unit configured to generate inserted k-space data by inserting the augmented k-space data into a target matrix whose format corresponds to identical sampling in the phase-encoding direction and the readout direction;
a back-transformation unit configured to transform the inserted k-space data into an image data domain, wherein undistorted high-resolution image data having border regions in the phase-encoding direction that contain no image information is generated; and
a cropping unit configured to generate formatted undistorted image data with increased resolution by cropping the border regions.

13. A magnetic resonance imaging system comprising an image data generating device as claimed in claim 11.

14. A non-transitory computer-readable storage medium comprising instructions which, when executed by a computer, cause the computer to carry out the steps of the method as claimed in claim 1.
